(19) United States
(12) Patent Application Publication
(10) Pub. No.: US 2025/0299848 A1
(43) Pub. Date: Sep. 25, 2025

(54) ELECTRONIC COMPONENT

(71) Applicant: Murata Manufacturing Co., Ltd., Nagaokakyo-shi (JP)

(72) Inventors: Yosuke MATSUSHITA, Nagaokakyo-shi (JP); Tomohiro YONEKURA, Nagaokakyo-shi (JP)

(21) Appl. No.: 19/231,670

(22) Filed: Jun. 9, 2025

Related U.S. Application Data
(63) Continuation of application No. PCT/JP2023/043136, filed on Dec. 1, 2023.

(30) Foreign Application Priority Data
Jan. 10, 2023 (JP) 2023-001469

(51) Int. Cl. H01B 5/14

(52) U.S. Cl. CPC H01B 5/14

(57) ABSTRACT

An electronic component includes a component main body, an external electrode, and a protective member. The component main body has a mounting surface, a left surface, a right surface, and a chamfered portion. The mounting surface is oriented in a down direction and is connected to the left surface through the chamfered portion. The chamfered portion extends along a front-back axis, when viewed in an up direction. The external electrode is provided on the mounting surface. The distance from the external electrode to the left surface is shorter than the distance from the external electrode to the right surface. The protective member is provided on the mounting surface and has a ring shape that covers the entirety of an external end of the external electrode.

### CROSS REFERENCE TO RELATED APPLICATION

This is a continuation of International Application No. PCT/JP2023/043136 filed on Dec. 1, 2023 which claims priority from Japanese Patent Application No. 2023-001469 filed on September Jan. 10, 2023. The contents of these applications are incorporated herein by reference in their entireties.

### BACKGROUND OF THE DISCLOSURE

### Field of the Disclosure

The present disclosure relates to an electronic component.

### Description of the Related Art

As a disclosure related to the conventional electronic component, for example, a ceramic electronic component described in Japanese Patent No. 5708798 is known. In this ceramic electronic component, a coating layer is provided so as to cover at least a part of a peripheral portion of an external terminal electrode provided on a ceramic layer. Accordingly, the peripheral portion of the external terminal electrode is protected. As a result, the external terminal electrode is prevented from peeling off from the ceramic layer.

### BRIEF SUMMARY OF THE DISCLOSURE

As described above, the field of the ceramic electronic component described in Japanese Patent No. 5708798 requires an external terminal electrode to be prevented from peeling off from a ceramic layer.

In view of the foregoing, exemplary embodiments of the present disclosure are directed to prevent an external electrode from peeling off from a component main body.

An electronic component according to one exemplary embodiment of the present disclosure includes a component main body, an external electrode, and a protective member; the component main body has a mounting surface, a left surface, a right surface, and a chamfered portion; the mounting surface is oriented in a down direction and is connected to the left surface through the chamfered portion; the chamfered portion extends along a front-back axis, when viewed in an up direction; the external electrode is provided on the mounting surface; a distance from the external electrode to the left surface is shorter than a distance from the external electrode to the right surface; the protective member is provided on the mounting surface and has a ring shape that covers an entirety of an external end of the external electrode; a cross-sectional surface that is parallel to an up-down axis and a left-right axis and passes an exposed portion in which the external electrode is exposed from the protective member is defined as a first cross-sectional surface; on the first cross-sectional surface, a center in a direction along the left-right axis of the exposed portion is defined as a central exposed portion; and, on the first cross-sectional surface, a left end of the external electrode is located above a right end of the external electrode, and/or on the first cross-sectional surface, a distance from the left end of the external electrode to the central exposed portion is shorter than a distance from the right end of the external electrode to the central exposed portion.

An electronic component according to one exemplary embodiment of the present disclosure includes a component main body, an external electrode, and a protective member; the component main body has a mounting surface, a left surface, a right surface, and a chamfered portion; the mounting surface is oriented in a down direction and is connected to the left surface through the chamfered portion; the chamfered portion extends along a front-back axis, when viewed in an up direction; the external electrode is provided on the mounting surface; a distance from the external electrode to the left surface is shorter than a distance from the external electrode to the right surface; the protective member is provided on the mounting surface and has a ring shape that covers an entirety of an external end of the external electrode; a cross-sectional surface that is parallel to an up-down axis and a left-right axis and passes an exposed portion in which the external electrode is exposed from the protective member is defined as a first cross-sectional surface; on the first cross-sectional surface, a center in a direction along the left-right axis of the exposed portion is defined as a central exposed portion; on the first cross-sectional surface, a virtual line that is line-symmetric with the chamfered portion with respect to a virtual line passing the central exposed portion and extending along the up-down axis is defined as a virtual chamfered portion; and, on the first cross-sectional surface, the shortest distance from the external electrode to the chamfered portion is longer than the shortest distance from the external electrode to the virtual chamfered portion.

The electronic component according to the present disclosure is able to prevent an external electrode from peeling off from a component main body.

### BRIEF DESCRIPTION OF THE SEVERAL VIEWS OF THE DRAWINGS

FIG. 1 is an external perspective view of an electronic component 10.

FIG. 2 is a bottom view of the electronic component 10.

FIG. 3 is a cross-sectional view taken along a line A-A of FIG. 2.

FIG. 4 is a cross-sectional view of an electronic component 10a.

### DETAILED DESCRIPTION OF THE DISCLOSURE

### Exemplary Embodiment

### (Structure of Electronic Component 10)

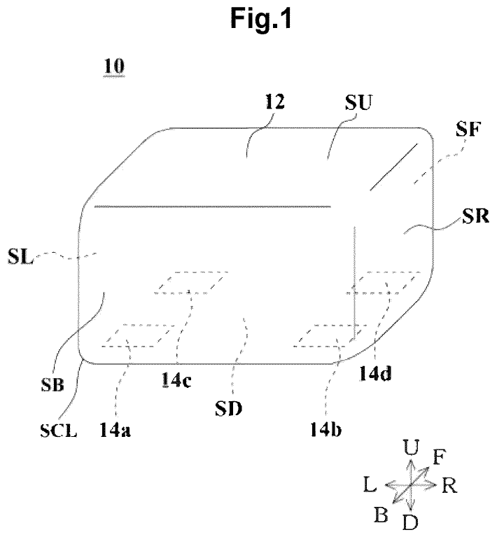

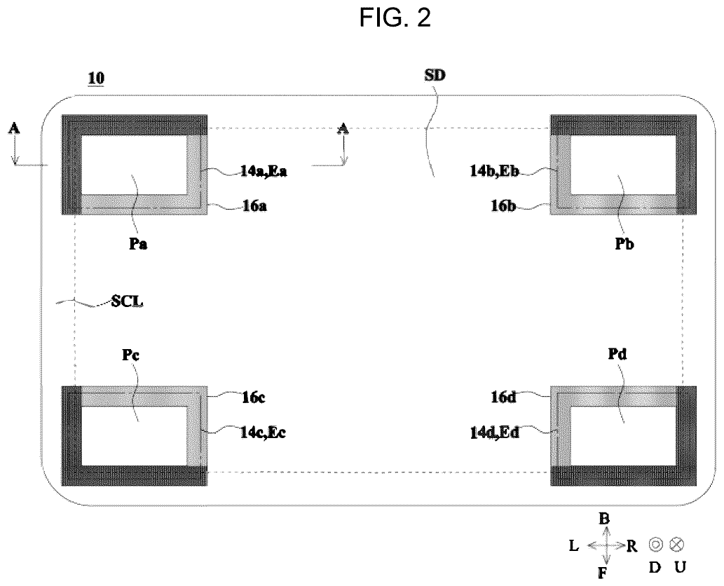

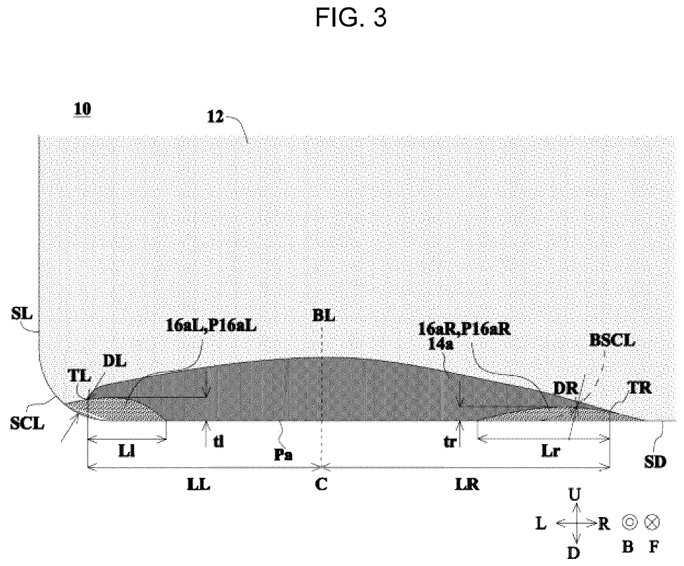

Hereinafter, a structure of an electronic component 10 according to exemplary embodiments of the present disclosure will be described with reference to drawings. FIG. 1 is an external perspective view of an electronic component 10. FIG. 2 is a bottom view of the electronic component 10. FIG. 3 is a cross-sectional view taken along a line A-A of FIG. 2.

In the present specification, directions are defined as follows. A direction in which a plurality of insulator layers are stacked is defined as an up-down direction. The directions orthogonal to the up-down direction are defined as a left-right direction and a front-back direction. The left-right direction and the front-back direction are orthogonal to each other. It is to be noted that the up-down direction, the front-back direction, and the left-right direction in the present exemplary embodiment may not match the up-down direction, the front-back direction, and the left-right direction during the use of the electronic component 10.

First, a structure of the electronic component 10 will be described with reference to FIG. 1 and FIG. 2. The electronic component 10 is, for example, used for a wireless-communication terminal such as a smartphone. As shown in FIG. 1, the electronic component 10 includes a component main body 12, external electrodes 14a to 14d, and protective members 16a to 16d.

The component main body 12 has a structure in which a plurality of insulator layers are stacked in the up-down direction. The component main body 12 has a rectangular parallelepiped shape. The component main body 12, as shown in FIG. 1, has an upper surface SU, a mounting surface SD, a left surface SL, a right surface SR, a front surface SF, and a back surface SB. The upper surface SU is oriented in the up direction. The mounting surface SD is oriented in the down direction. The left surface SL, the right surface SR, the front surface SF, and the back surface SB are side surfaces located between the mounting surface SD and the upper surface SU.

In addition, each edge of the component main body 12 is chamfered. Therefore, the component main body 12 has a chamfered portion SCL. The chamfered portion SCL is rounded so as to expand in a direction away from the center of the component main body 12. The mounting surface SD is connected to the left surface SL through the chamfered portion SCL. As shown in FIG. 2, the chamfered portion SCL extends along a front-back axis, when viewed in the up direction. The material of the component main body 12 as described above is ceramic.

The external electrodes 14a to 14d are provided on the mounting surface SD. The external electrode 14a is located near a left back corner of the mounting surface SD. The distance from the external electrode 14a to the left surface SL is shorter than the distance from the external electrode 14a to the right surface SR. The external electrode 14b is located near a right back corner of the mounting surface SD. The distance from the external electrode 14b to the right surface SR is shorter than the distance from the external electrode 14b to the left surface SL. The external electrode 14c is located near a left front corner of the mounting surface SD. The distance from the external electrode 14c to the left surface SL is shorter than the distance from the external electrode 14c to the right surface SR. The external electrode 14d is located near a right front corner of the mounting surface SD. The distance from the external electrode 14d to the right surface SR is shorter than the distance from the external electrode 14d to the left surface SL. The external electrodes 14a to 14d have a rectangular shape when viewed in the up direction. Accordingly, the external electrodes 14a to 14d respectively have rectangular external ends Ea to Ed when viewed in the up direction.

The protective members 16a to 16d are provided on the mounting surface SD. The protective members 16a to 16d have a ring shape that covers the entirety of the external ends Ea to Ed of the external electrodes 14a to 14d. Specifically, the protective members 16a to 16d have a rectangular ring shape, when viewed in the up direction. In addition, the protective members 16a to 16d respectively overlap with the entirety of the external ends Ea to Ed, when viewed in the up direction. Then, the external electrodes 14a to 14d respectively have exposed portions Pa to Pd exposed from the protective members 16a to 16d. The exposed portions Pa to Pd are respectively surrounded by the protective members 16a to 16d, when viewed in the up direction. The material of the protective members 16a to 16d as described above is ceramic. The material of the protective members 16a to 16d is the same as the material of the component main body 12.

Herein, the external electrode 14a and the protective member 16a are used as an example, and the details of the external electrode 14a and the protective member 16a will be described. The cross-sectional surface that is parallel to the up-down axis and the left-right axis and passes the exposed portion Pa in which the external electrode 14a is exposed from the protective member 16a is defined as a first cross-sectional surface. FIG. 3 is a cross-sectional view of the first cross-sectional surface.

First, on the first cross-sectional surface, the center in a direction along the left-right axis of the exposed portion Pa is defined as a central exposed portion C. Furthermore, on the first cross-sectional surface, a virtual line that is line-symmetric with the chamfered portion SCL with respect to a virtual line BL passing the central exposed portion C and extending along the up-down axis is defined as a virtual chamfered portion BSCL.

As shown in FIG. 3, on the first cross-sectional surface, the protective member 16a includes a left portion 16aL that overlaps with a left end TL of the external electrode 14a in the up-down axis, and a right portion 16aR that overlaps with a right end TR of the external electrode 14a in the up-down axis. Then, the thickness t1 of the left portion 16aL in the up-down axis is larger than the thickness tr of the right portion 16aR in the up-down axis. Accordingly, on the first cross-sectional surface, the left end TL of the external electrode 14a is located above the right end TR of the external electrode 14a.

In addition, as shown in FIG. 2, the thickness of a left side and a back side of the protective member 16a in the up-down axis is larger than the thickness of a right side and a front side of the protective member 16a in the up-down axis. In such a manner, of the four sides of the protective member 16a, the thickness of two sides located near the external end of the mounting surface SD in the up-down axis is large.

Furthermore, on the first cross-sectional surface, the left end TL of the external electrode 14a overlaps with the chamfered portion SCL in the up-down axis. However, on the first cross-sectional surface, a distance LL from the left end TL of the external electrode 14a to the central exposed portion C is shorter than a distance LR from the right end TR of the external electrode 14a to the central exposed portion C. Accordingly, on the first cross-sectional surface, the shortest distance DL from the external electrode 14a to the chamfered portion SCL is longer than the shortest distance DR from the external electrode 14a to the virtual chamfered portion BSCL. In the present exemplary embodiment, the shortest distance DR is 0. Accordingly, the external electrode 14a is not exposed from the chamfered portion SCL.

Furthermore, on the first cross-sectional surface, a length L1 of a left overlapping portion P16aL in a direction along the left-right axis, the left overlapping portion being a portion in which the left portion 16aL overlaps with the external electrode 14a in the up-down axis, is shorter than a length Lr of a right overlapping portion P16aR in the direction along the left-right axis, the right overlapping portion being a portion in which the right portion 16aR overlaps with the external electrode 14a in the up-down axis. It is to be noted that, since the structures of the external electrodes 14b to 14d are the same as the structure of the external electrode 14a, the description will be omitted.

The electronic components 10 as described above is mounted on a circuit board with solder. The solder is applied to the external electrodes 14a to 14d. Then, the external electrodes 14a to 14d are fixed to the external electrode of the circuit board with the solder.

### (Effects)

In the electronic component 10, the protective members 16a to 16d have a ring shape that covers the entirety of the external ends Ea to Ed of the external electrodes 14a to 14d. Accordingly, the external electrode 14a is able to be prevented from peeling off from the component main body 12. In particular, when the material of the protective members 16a to 16d is the same as the material of the component main body 12, the adhesiveness of the protective members 16a to 16d with respect to the component main body 12 is enhanced. As a result, the external electrode 14a is able to be more effectively prevented from peeling off from the component main body 12.

In the electronic component 10, while the miniaturization of the electronic component 10 is achieved, the external electrode 14a is prevented from being exposed from the chamfered portion SCL. On the first cross-sectional surface, the left end TL of the external electrode 14a overlaps with the chamfered portion SCL in the up-down axis. Accordingly, the left surface SL is located near the external electrode 14a. Therefore, the miniaturization of the electronic component 10 is achieved. However, in this case, a possibility that the left end TL of the external electrode 14a is exposed from the chamfered portion SCL is increased. Therefore, on the first cross-sectional surface, the distance LL from the left end TL of the external electrode 14a to the central exposed portion C is shorter than the distance LR from the right end TR of the external electrode 14a to the central exposed portion C. Accordingly, on the first cross-sectional surface, the shortest distance DL from the external electrode 14a to the chamfered portion SCL is longer than the shortest distance DR from the external electrode 14a to the virtual chamfered portion BSCL. As a result, the left end TL of the external electrode 14a is away from the chamfered portion SCL. Therefore, the external electrode 14a is prevented from exposing from the chamfered portion SCL.

In the electronic component 10, also for the following reason, while the miniaturization of the electronic component 10 is achieved, the external electrode 14a is prevented from being exposed from the chamfered portion SCL. On the first cross-sectional surface, the left end TL of the external electrode 14a overlaps with the chamfered portion SCL in the up-down axis. Accordingly, the left surface SL is located near the external electrode 14a. Therefore, the miniaturization of the electronic component 10 is achieved. However, in this case, the possibility that the left end TL of the external electrode 14a is exposed from the chamfered portion SCL is increased. Then, on the first cross-sectional surface, the left end TL of the external electrode 14a is located above the right end TR of the external electrode 14a. Accordingly, on the first cross-sectional surface, the shortest distance DL from the external electrode 14a to the chamfered portion SCL is longer than the shortest distance DR from the external electrode 14a to the virtual chamfered portion BSCL. As a result, the left end TL of the external electrode 14a is away from the chamfered portion SCL. Therefore, the external electrode 14a is prevented from exposing from the chamfered portion SCL.

### (Modification)

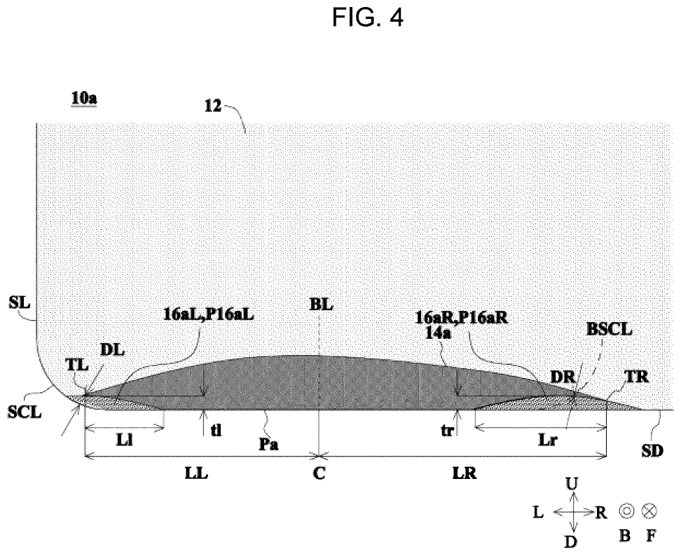

Hereinafter, an electronic component 10a according to a modification of the present disclosure will be described with reference to drawings. FIG. 4 is a cross-sectional view of the electronic component 10a.

The electronic component 10a is different from the electronic component 10 in that the thickness t1 of the left portion 16aL in the up-down axis is substantially equal to the thickness tr of the right portion 16aR in the up-down axis. Therefore, on the first cross-sectional surface, the location of the left end TL of the external electrode 14a in the up-down axis is substantially equal to the location of the right end TR of the external electrode 14a in the up-down axis.

However, on the first cross-sectional surface, the distance LL from the left end TL of the external electrode 14a to the central exposed portion C is shorter than the distance LR from the right end TR of the external electrode 14a to the central exposed portion C. Furthermore, on the first cross-sectional surface, the length L1 of the left overlapping portion P16aL in the direction along the left-right axis, the left overlapping portion being a portion in which the left portion 16aL overlaps with the external electrode 14a in the up-down axis, is shorter than the length Lr of a right overlapping portion P16aR in the direction along the left-right axis, the right overlapping portion being a portion in which the right portion 16aR overlaps with the external electrode 14a in the up-down axis. Accordingly, on the first cross-sectional surface, the shortest distance DL from the external electrode 14a to the chamfered portion SCL is longer than the shortest distance DR from the external electrode 14a to the virtual chamfered portion BSCL. Since the remaining structure of the electronic component 10a is the same as the structure of the electronic component 10, the description will be omitted. The electronic component 10a has the same advantageous effects as the electronic component 10.

### Other Exemplary Embodiments

Electronic components according to the present disclosure are not limited to the electronic components 10 and 10a and various changes and modifications may be possible within the scope of the present disclosure. In addition, the structures of the electronic components 10 and 10a may be optionally combined.

It is to be noted that at least one of the following may hold: on the first cross-sectional surface, the left end TL of the external electrode 14a is located above the right end TR of the external electrode 14a, or, on the first cross-sectional surface, the distance LL from the left end TL of the external electrode 14a to the central exposed portion C is shorter than the distance LR from the right end TR of the external electrode 14a to the central exposed portion C.

The material of the protective members 16a to 16d may not be ceramic.

The material of the component main body 12 may not be ceramic.

The material of the protective members 16a to 16d may be different from the material of the component main body 12.

On the first cross-sectional surface, the left end TL of the external electrode 14a may not overlap with the chamfered portion SCL in the up-down axis.

It is to be noted that, on the first cross-sectional surface, the length L1 of the left overlapping portion P16aL in the direction along the left-right axis, the left overlapping portion being a portion in which the left portion 16aL overlaps with the external electrode 14a in the up-down axis, may not be shorter than the length Lr of a right overlapping portion P16aR in the direction along the left-right axis, the right overlapping portion being a portion in which the right portion 16aR overlaps with the external electrode 14a in the up-down axis.

The present disclosure includes the following structures.
(1) An electronic component includes a component main body, an external electrode, and a protective member; the component main body has a mounting surface, a left surface, a right surface, and a chamfered portion; the mounting surface is oriented in a down direction and is connected to the left surface through the chamfered portion; the chamfered portion extends along a front-back axis, when viewed in an up direction; the external electrode is provided on the mounting surface; a distance from the external electrode to the left surface is shorter than a distance from the external electrode to the right surface; the protective member is provided on the mounting surface and has a ring shape that covers an entirety of an external end of the external electrode; a cross-sectional surface that is parallel to an up-down axis and a left-right axis and passes an exposed portion in which the external electrode is exposed from the protective member is defined as a first cross-sectional surface; on the first cross-sectional surface, a center in a direction along the left-right axis of the exposed portion is defined as a central exposed portion; and, on the first cross-sectional surface, a left end of the external electrode is located above a right end of the external electrode, and/or, on the first cross-sectional surface, a distance from the left end of the external electrode to the central exposed portion is shorter than a distance from the right end of the external electrode to the central exposed portion.
(2) The electronic component according to (1) in which, on the first cross-sectional surface, the protective member includes: a left portion that overlaps with the left end of the external electrode in the up-down axis; and a right portion that overlaps with the right end of the external electrode in the up-down axis; and a thickness of the left portion in the up-down axis is larger than a thickness of the right portion in the up-down axis.
(3) The electronic component according to (1) or (2) in which a material of the protective member is ceramic.
(4) The electronic component according to (3) in which a material of the component main body is ceramic.
(5) The electronic component according to (4) in which the material of the protective member is the same as the material of the component main body.
(6) The electronic component according to any one of (1) to (5) in which, on the first cross-sectional surface, the left end of the external electrode overlaps with the chamfered portion in the up-down axis.
(7) The electronic component according to any one of (1) to (6) in which, on the first cross-sectional surface, the protective member includes a left portion that overlaps with the left end of the external electrode in the up-down axis, and a right portion that overlaps with the right end of the external electrode in the up-down axis; and, on the first cross-sectional surface, a length of a left overlapping portion in a direction along the left-right axis, the left overlapping portion being a portion in which the left portion overlaps with the external electrode in the up-down axis, is shorter than a length of a right overlapping portion in the direction along the left-right axis, the right overlapping portion being a portion in which the right portion overlaps with the external electrode in the up-down axis.
(8) An electronic component includes a component main body, an external electrode, and a protective member; the component main body has a mounting surface, a left surface, a right surface, and a chamfered portion; the mounting surface is oriented in a down direction and is connected to the left surface through the chamfered portion; the chamfered portion extends along a front-back axis, when viewed in an up direction; the external electrode is provided on the mounting surface; a distance from the external electrode to the left surface is shorter than a distance from the external electrode to the right surface; the protective member is provided on the mounting surface and has a ring shape that covers an entirety of an external end of the external electrode; a cross-sectional surface that is parallel to an up-down axis and a left-right axis and passes an exposed portion in which the external electrode is exposed from the protective member is defined as a first cross-sectional surface; on the first cross-sectional surface, a center in a direction along the left-right axis of the exposed portion is defined as a central exposed portion; on the first cross-sectional surface, a virtual line that is line-symmetric with the chamfered portion with respect to a virtual line passing the central exposed portion and extending along the up-down axis is defined as a virtual chamfered portion; and, on the first cross-sectional surface, the shortest distance from the external electrode to the chamfered portion is longer than the shortest distance from the external electrode to the virtual chamfered portion.
10, 10a: electronic component
12: component main body
14a to 14d: external electrode
16a to 16d: protective member
16aL: left portion
16aR: right portion
BL: virtual line
BSCL: virtual chamfered portion
C: central exposed portion
Ea: external end
P16aL: left overlapping portion
P16aR: right overlapping portion
Pa: exposed portion
SB: back surface
SCL: chamfered portion
SD: mounting surface
SF: front surface
SL: left surface
SR: right surface
SU: upper surface
TL: left end
TR: right end

1. An electronic component comprising:
a component main body;
an external electrode; and
a protective member, wherein:
the component main body has a mounting surface, a left surface, a right surface, and a chamfered portion;
the mounting surface is oriented in a down direction and is connected to the left surface through the chamfered portion;
the chamfered portion extends along a front-back axis, when viewed in an up direction;
the external electrode is provided on the mounting surface;
a distance from the external electrode to the left surface is shorter than a distance from the external electrode to the right surface;
the protective member is provided on the mounting surface and has a ring shape covering an entirety of an external end of the external electrode;
a cross-sectional surface being parallel to an up-down axis and a left-right axis and passing an exposed portion in which the external electrode is exposed from the protective member is defined as a first cross-sectional surface;
on the first cross-sectional surface, a center in a direction along the left-right axis of the exposed portion is defined as a central exposed portion; and
on the first cross-sectional surface, a left end of the external electrode is located above a right end of the external electrode, and/or, on the first cross-sectional surface, a distance from the left end of the external electrode to the central exposed portion is shorter than a distance from the right end of the external electrode to the central exposed portion.

2. The electronic component according to claim 1, wherein:
on the first cross-sectional surface, the protective member includes:
a left portion overlapping with the left end of the external electrode in the up-down axis; and
a right portion overlapping with the right end of the external electrode in the up-down axis; and
a thickness of the left portion in the up-down axis is greater than a thickness of the right portion in the up-down axis.

3. The electronic component according to claim 2, wherein, on the first cross-sectional surface, a length of a left overlapping portion in a direction along the left-right axis, the left overlapping portion being a portion in which the left portion overlaps with the external electrode in the up-down axis, is shorter than a length of a right overlapping portion in the direction along the left-right axis, the right overlapping portion being a portion in which the right portion overlaps with the external electrode in the up-down axis.

4. The electronic component according to claim 1, wherein a material of the protective member is ceramic.

5. The electronic component according to claim 4, wherein a material of the component main body is ceramic.

6. The electronic component according to claim 5, wherein the material of the protective member is same as the material of the component main body.

7. The electronic component according to claim 1, wherein, on the first cross-sectional surface, the left end of the external electrode overlaps with the chamfered portion in the up-down axis.

8. The electronic component according to claim 1, wherein:
on the first cross-sectional surface, the protective member includes:
a left portion overlapping with the left end of the external electrode in the up-down axis; and
a right portion overlapping with the right end of the external electrode in the up-down axis; and
on the first cross-sectional surface, a length of a left overlapping portion in a direction along the left-right axis, the left overlapping portion being a portion in which the left portion overlaps with the external electrode in the up-down axis, is shorter than a length of a right overlapping portion in the direction along the left-right axis, the right overlapping portion being a portion in which the right portion overlaps with the external electrode in the up-down axis.

9. An electronic component comprising:
a component main body;
an external electrode; and
a protective member, wherein:
the component main body has a mounting surface, a left surface, a right surface, and a chamfered portion;
the mounting surface is oriented in a down direction and is connected to the left surface through the chamfered portion;
the chamfered portion extends along a front-back axis, when viewed in an up direction;
the external electrode is provided on the mounting surface;
a distance from the external electrode to the left surface is shorter than a distance from the external electrode to the right surface;
the protective member is provided on the mounting surface and has a ring shape covering an entirety of an external end of the external electrode;
a cross-sectional surface being parallel to an up-down axis and a left-right axis and passing an exposed portion in which the external electrode is exposed from the protective member is defined as a first cross-sectional surface;
on the first cross-sectional surface, a center in a direction along the left-right axis of the exposed portion is defined as a central exposed portion;
on the first cross-sectional surface, a virtual line being line-symmetric with the chamfered portion with respect to a virtual line passing the central exposed portion and extending along the up-down axis is defined as a virtual chamfered portion; and
on the first cross-sectional surface, a shortest distance from the external electrode to the chamfered portion is longer than a shortest distance from the external electrode to the virtual chamfered portion.

10. The electronic component according to claim 2, wherein a material of the protective member is ceramic.

11. The electronic component according to claim 3, wherein a material of the protective member is ceramic.

12. The electronic component according to claim 2, wherein, on the first cross-sectional surface, the left end of the external electrode overlaps with the chamfered portion in the up-down axis.

13. The electronic component according to claim 3, wherein, on the first cross-sectional surface, the left end of the external electrode overlaps with the chamfered portion in the up-down axis.

14. The electronic component according to claim 4, wherein, on the first cross-sectional surface, the left end of the external electrode overlaps with the chamfered portion in the up-down axis.

15. The electronic component according to claim 5, wherein, on the first cross-sectional surface, the left end of the external electrode overlaps with the chamfered portion in the up-down axis.

16. The electronic component according to claim 6, wherein, on the first cross-sectional surface, the left end of the external electrode overlaps with the chamfered portion in the up-down axis.

17. The electronic component according to claim 2, wherein:
on the first cross-sectional surface, the protective member includes:
a left portion overlapping with the left end of the external electrode in the up-down axis; and
a right portion overlapping with the right end of the external electrode in the up-down axis; and
on the first cross-sectional surface, a length of a left overlapping portion in a direction along the left-right axis, the left overlapping portion being a portion in which the left portion overlaps with the external electrode in the up-down axis, is shorter than a length of a right overlapping portion in the direction along the left-right axis, the right overlapping portion being a portion in which the right portion overlaps with the external electrode in the up-down axis.

18. The electronic component according to claim 3, wherein:
on the first cross-sectional surface, the protective member includes:
a left portion overlapping with the left end of the external electrode in the up-down axis; and
a right portion overlapping with the right end of the external electrode in the up-down axis; and
on the first cross-sectional surface, a length of a left overlapping portion in a direction along the left-right axis, the left overlapping portion being a portion in which the left portion overlaps with the external electrode in the up-down axis, is shorter than a length of a right overlapping portion in the direction along the left-right axis, the right overlapping portion being a portion in which the right portion overlaps with the external electrode in the up-down axis.

19. The electronic component according to claim 4, wherein:
on the first cross-sectional surface, the protective member includes:
a left portion overlapping with the left end of the external electrode in the up-down axis; and
a right portion overlapping with the right end of the external electrode in the up-down axis; and
on the first cross-sectional surface, a length of a left overlapping portion in a direction along the left-right axis, the left overlapping portion being a portion in which the left portion overlaps with the external electrode in the up-down axis, is shorter than a length of a right overlapping portion in the direction along the left-right axis, the right overlapping portion being a portion in which the right portion overlaps with the external electrode in the up-down axis.

20. The electronic component according to claim 5, wherein:
on the first cross-sectional surface, the protective member includes:
a left portion overlapping with the left end of the external electrode in the up-down axis; and
a right portion overlapping with the right end of the external electrode in the up-down axis; and
on the first cross-sectional surface, a length of a left overlapping portion in a direction along the left-right axis, the left overlapping portion being a portion in which the left portion overlaps with the external electrode in the up-down axis, is shorter than a length of a right overlapping portion in the direction along the left-right axis, the right overlapping portion being a portion in which the right portion overlaps with the external electrode in the up-down axis.
